(19) United States
(12) Patent Application Publication
(10) Pub. No.: US 2024/0336835 A1
(43) Pub. Date: Oct. 10, 2024

(54) METAL COMPLEX PHOSPHOR, METHOD OF PRODUCING METAL COMPLEX PHOSPHOR, PHOSPHOR SHEET COMPRISING METAL COMPLEX PHOSPHOR, AND LIGHT EMITTING DEVICE COMPRISING PHOSPHOR SHEET

(71) Applicant: NICHIA CORPORATION, Anan-shi (JP)

(72) Inventors: Hiroshi OGASA, Tokushima-shi (JP); Hiroki INOUE, Naruto-shi (JP); Kenichi AOYAGI, Itano-gun (JP)

(73) Assignee: NICHIA CORPORATION, Anan-shi (JP)

(21) Appl. No.: 18/627,015

(22) Filed: Apr. 4, 2024

(30) Foreign Application Priority Data
Apr. 6, 2023 (JP) 2023-062203
Jan. 30, 2024 (JP) 2024-012136

(51) Int. Cl. C09K 11/06

(52) U.S. Cl. CPC C09K 11/06; C09K 2211/182

(57) ABSTRACT

An object of the present invention is to provide: a rare earth metal complex phosphor having an extended durability; and a method of producing such a rare earth metal complex phosphor; and the like. Provided is a method of producing a metal complex phosphor having an emission peak wavelength of 600 nm to 635 nm, the method comprising: preparing a ligand that is represented by Chemical Formula (I) and comprises two sets of azomethine groups, and dissolving this ligand in a first solvent to prepare a solution (1); preparing a rare earth metal complex that comprises a β-diketonato ligand represented by Chemical Formula (II) but does not comprise the ligand represented by Chemical Formula (I), and dissolving this rare earth metal complex in a second solvent to prepare a solution (2); mixing the solution (1) and the solution (2).

### TECHNICAL FIELD

The present disclosure relates to: a metal complex phosphor; a method of producing a metal complex phosphor; a phosphor sheet comprising a metal complex phosphor; a light emitting device comprising a phosphor sheet; and the like.

### BACKGROUND ART

Rare earth metal complexes are expected to be used as light emitting members such as fluorescent probes, laser emitters, bioimaging members, sensors, security inks, and lighting instruments. Particularly, rare earth metal complexes can be excited by, for example, a relatively short-wavelength blue visible light to emit a long-wavelength light; therefore, it is expected that light emitting devices having various emission colors can be realized by combining such rare earth metal complexes with semiconductor light emitting elements such as light emitting diodes. Since those light emitting devices using semiconductor light emitting elements such as light emitting diodes (LED) and laser diodes (LD) have a high emission efficiency and contain no harmful substance such as mercury, their use are expected to be further expanded to the lighting applications and the image display applications, including liquid crystal display devices. Recently, light emitting devices combining a light emitting diode or a laser diode with a light emitting member formed of a rare earth metal complex have been actively studied.

Patent Literature 1 and Non-patent Literature 1 report that: compositions comprising a novel rare earth metal complex were synthesized, their emission characteristics were examined, and these compositions were found to have interesting emission characteristics; and light emitting devices combining the compositions with a light emitting diode or a laser diode were developed.

Further, Patent Document 2 reports: a rare earth metal complex having a broad excitation wavelength range (i.e., this rare earth metal complex absorbs light having a wavelength in the ultraviolet to visible light region and generates a light having a longer wavelength than the absorbed light) and a high external quantum efficiency; and a method of producing the same.

### CITATION LIST

### Patent Literature

[Patent Literature 1] JP 2016-128392 A
[Patent Literature 2] JP 2019-31446 A

### Non-Patent Literature

[Non-patent Literature 1] “Chemistry-A European Journal”, vol. 17, 2011, p. 521-528

### SUMMARY OF INVENTION

### Technical Problem

More specifically, the rare earth metal complex disclosed in Non-patent Literature 2 is characterized by absorbing blue light to generate red light, and having a high color purity. However, this rare earth metal complex does not necessarily have sufficient durability and is thus demanded to have a higher durability.

An object of the present invention is to provide: a rare earth metal complex phosphor having an extended durability; and a method of producing such a rare earth metal complex phosphor; and the like.

### Solution to Problem

The present specification encompasses the following embodiments.

1. A method of producing a metal complex phosphor having an emission peak wavelength of 600 nm to 635 nm, the method comprising:
preparing a ligand that is represented by the following Chemical Formula (I) and comprises two sets of azomethine groups, and dissolving this ligand in a first solvent to prepare a solution (1);
preparing a rare earth metal complex that comprises a β-diketonato ligand represented by the following Chemical Formula (II) but does not comprise the ligand represented by Chemical Formula (I), and dissolving this rare earth metal complex in a second solvent to prepare a solution (2); and
mixing the solution (1) and the solution (2):

### Chemical Formula (I):

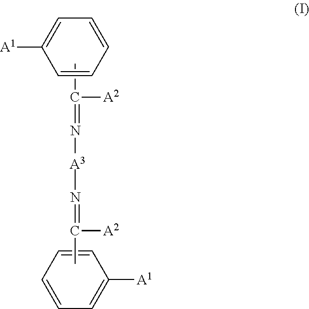 [0015] [wherein,
A¹ represents an OH group, an OD group, an SH group, or an SD group,
A² is selected from hydrogen, deuterium, C1 to C30 alkyl groups, C3 to C30 cycloalkyl groups, C1 to C30 perhalogenated alkyl groups, and C3 to C30 perhalogenated cycloalkyl groups, which groups optionally have one or more substituents selected from the following group (G):
aromatic groups;
perhalogenated aromatic groups;
heteroaromatic groups comprising at least one heteroatom in a ring;
linear or branched C1 to C30 alkyl groups;
linear or branched C1 to C30 perhalogenated alkyl groups;
linear or branched C3 to C30 alkenyl groups;
linear or branched C3 to C30 perhalogenated alkenyl groups;
C3 to C30 cycloalkyl groups;
C3 to C30 perhalogenated cycloalkyl groups;
C3 to C30 cycloalkenyl groups;
C3 to C30 perhalogenated cycloalkenyl groups; and
C3 to C30 alkynyl groups, and
halogeno groups,
A³ is selected from C2 to C30 alkylene groups optionally having one or more substituents selected from the group (G) and halogeno groups,
regarding a benzene ring to which A¹ and an azomethine group are both bound, two adjacent carbon atoms of the benzene ring that are not bound with A¹ and the azomethine group are optionally connected via —C₄H₄— to form a naphthalene ring, and
the benzene ring and the optionally-formed naphthalene ring optionally further have one or more substituents selected from the group (G) and halogeno groups]; and

### Chemical Formula (II):

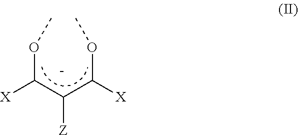 [0035] [wherein,
Xs represent substituents that are optionally the same as or different from each other and are selected from the group (G), and
Z represents a fluorine atom, a chlorine atom, a bromine atom, an iodine atom, a cyano group, a methyl group, an ethyl group, a phenyl group, a hydrogen atom, or a deuterium atom].
   2. A metal complex phosphor, comprising a rare earth metal complex and having a D50 particle size of 12 μm to 100 μm,
wherein
the rare earth metal complex comprises at least one chemical structure selected from the following Chemical Formulae (III) and (IV),
the rare earth metal is 8-coordinate, and
the metal complex phosphor has an emission peak wavelength of 600 nm to 635 nm:

### Chemical Formula (III):

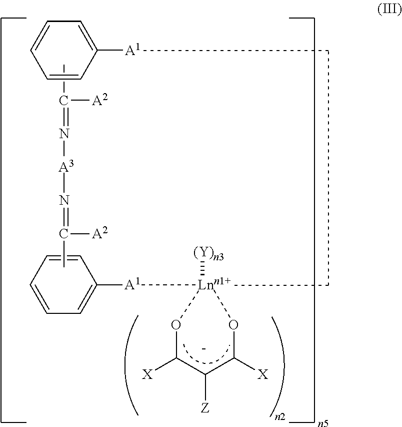 [0043] [wherein,
Ln represents a rare earth metal atom,
n1 represents 2 or 3,
regarding a β-diketonato ligand, Xs represent substituents that are optionally the same as or different from each other and are selected from the following group (G):
aromatic groups;
perhalogenated aromatic groups;
heteroaromatic groups comprising at least one heteroatom in a ring;
linear or branched C1 to C30 alkyl groups;
linear or branched C1 to C30 perhalogenated alkyl groups;
linear or branched C3 to C30 alkenyl groups;
linear or branched C3 to C30 perhalogenated alkenyl groups;
C3 to C30 cycloalkyl groups;
C3 to C30 perhalogenated cycloalkyl groups;
C3 to C30 cycloalkenyl groups;
C3 to C30 perhalogenated cycloalkenyl groups; and
C3 to C30 alkynyl groups,
Z represents a fluorine atom, a chlorine atom, a bromine atom, an iodine atom, a cyano group, a methyl group, an ethyl group, a phenyl group, a hydrogen atom, or a deuterium atom,
n2 represents an integer of 1 to 3,
Y is optionally at least one selected from a perchlorate ion, a nitrate ion, a carboxylate ion, and a halide ion,
n3 represents an integer of 0 to 2,
regarding a ligand that comprises two sets of azomethine groups:
A¹ represents an OH group, an OD group, an SH group, or an SD group,
A² is selected from hydrogen, deuterium, C1 to C30 alkyl groups, C3 to C30 cycloalkyl groups, C1 to C30 perhalogenated alkyl groups, and C3 to C30 perhalogenated cycloalkyl groups, which groups optionally have one or more substituents selected from the group (G) and halogeno groups,
A³ is selected from C2 to C30 alkylene groups optionally having one or more substituents selected from the group (G) and halogeno groups,
regarding a benzene ring to which A¹ and an azomethine group are both bound, two adjacent carbon atoms of the benzene ring that are not bound with A¹ and the azomethine group are optionally connected via —C₄H₄— to form a naphthalene ring,
the benzene ring and the optionally-formed naphthalene ring optionally further have one or more substituents selected from the group (G) and halogeno groups, and
n5 represents an integer of 2 or larger]; and

### Chemical Formula (IV):

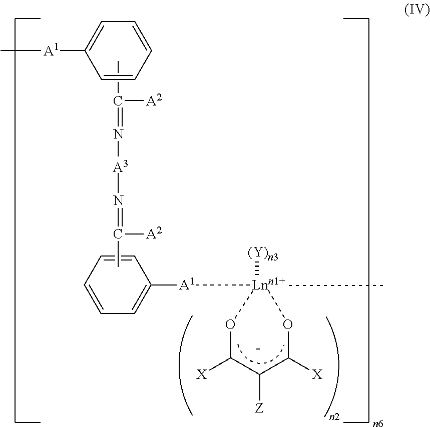 [0071] [wherein, all symbols have the same meaning as in Chemical Formula (III), except that n6 represents an integer of 1 or larger].

### Advantageous Effects of Invention

The rare earth metal complex phosphor according to one embodiment of the present invention can have an extended durability. Therefore, the rare earth metal complex phosphor according to one embodiment of the present invention can be suitably used for the production of a phosphor sheet and a light emitting device.

### BRIEF DESCRIPTION OF DRAWINGS

FIG. 1 shows chemical formulae of the ligands according to one embodiment of the present invention.

FIG. 2 shows the chemical structures comprised in the metal complex phosphor according to one embodiment of the present invention.

FIG. 3 shows an SEM image (×1,000) of the metal complex of Example 1.

FIG. 4 shows an SEM image (×2,000) of the metal complex of Comparative Example 1.

FIG. 5 shows an FT-IR spectrum of the metal complex of Example 1.

FIG. 6 shows an FT-IR spectrum of the metal complex of Comparative Example 1.

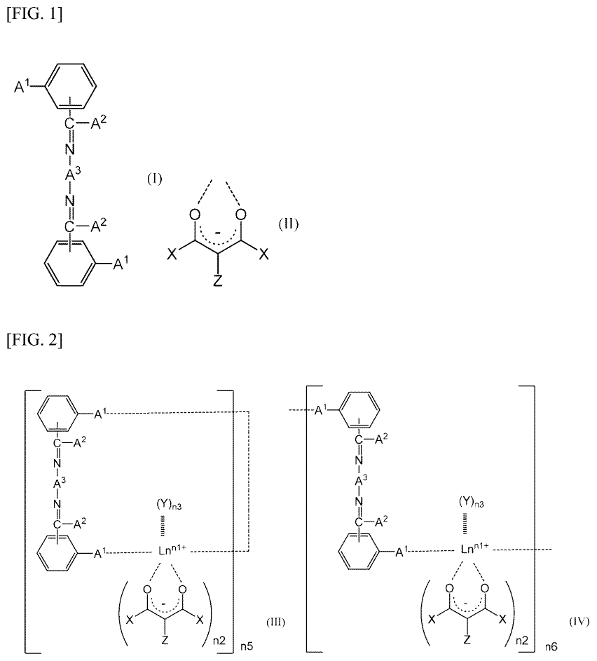

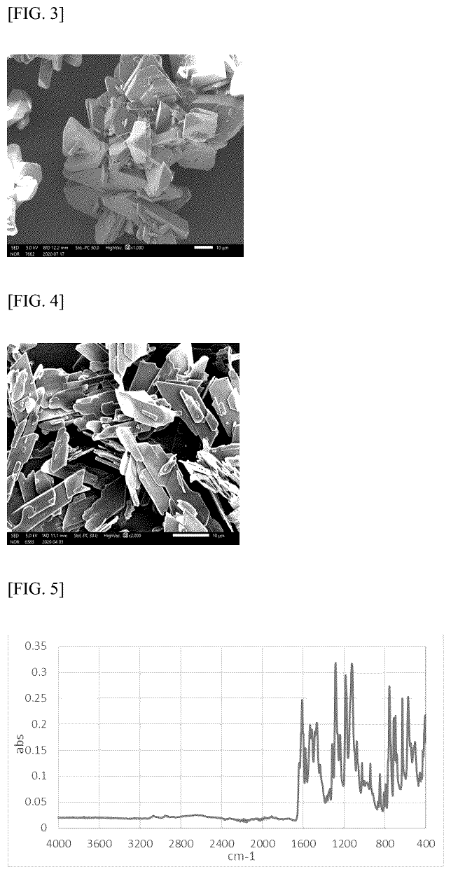

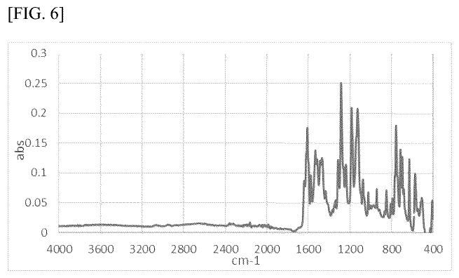

### DESCRIPTION OF EMBODIMENTS

In one embodiment of the present invention, a novel method of producing a metal complex phosphor having an emission peak wavelength of 600 nm to 635 nm is provided. This method comprises:
preparing a ligand that is represented by the following Chemical Formula (I) and comprises two sets of azomethine groups, and dissolving this ligand in a first solvent to prepare a solution (1);
preparing a rare earth metal complex that comprises a β-diketonato ligand represented by the following Chemical Formula (II) but does not comprise the ligand represented by Chemical Formula (I), and dissolving this rare earth metal complex in a second solvent to prepare a solution (2); and
mixing the solution (1) and the solution (2):
   a ligand that is represented by Chemical Formula (I) and comprises two sets of hydroxy groups or thiol groups and azomethine groups:

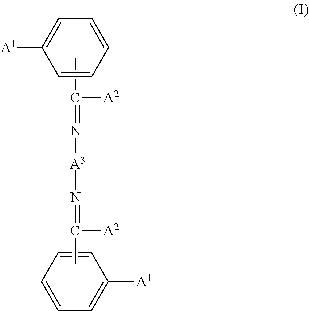

[wherein,
A¹ represents an OH group, an OD group, an SH group, or an SD group,
A² is selected from hydrogen, deuterium, C1 to C30 alkyl groups (—CₙH₂ₙ₊₁: wherein, n=1 to 30, preferably n=1 to 18, more preferably n=1 to 6, particularly preferably n=1 to 3), C3 to C30 cycloalkyl groups (—CₙH₂ₙ₋₁: wherein, n=3 to 30, preferably n=3 to 18, more preferably n=3 to 6, particularly preferably n=3), C1 to C30 perhalogenated alkyl groups (for example, —CₙF₂ₙ₊₁ and —CₙCl₂ₙ₊₁, preferably-CₙF₂ₙ₊₁: wherein, n=1 to 30, preferably n=1 to 18, more preferably n=1 to 6, particularly preferably n=1 to 3), and C3 to C30 perhalogenated cycloalkyl groups (for example, —CₙF₂ₙ₋₁ and —CₙCl₂ₙ₋₁, preferably —CₙF₂ₙ₋₁: wherein, n=3 to 30, preferably n=3 to 18, more preferably n=3 to 6, particularly preferably n=3), which groups optionally have one or more substituents selected from the following group (G1):
aromatic groups, such as a phenyl group, a naphthyl group, and a biphenyl group;
perhalogenated aromatic groups, such as a perfluorophenyl group, a perfluoronaphthyl group, a perfluorobiphenyl group, a perchlorophenyl group, a perchloronaphthyl group, and a perchlorobiphenyl group;
heteroaromatic groups comprising at least one heteroatom selected from N, O, S, and the like in a ring;
linear or branched C1 to C30 alkyl groups (CₙH₂ₙ₊₁: n=1 to 30);
linear or branched C1 to C30 perhalogenated alkyl groups, such as perfluoroalkyl groups (CₙF₂ₙ₊₁: n=1 to 30) and perchloroalkyl groups (CₙCl₂ₙ₊₁: n=1 to 30);
linear or branched C3 to C30 alkenyl groups, such as a butenyl group;
linear or branched C3 to C30 perhalogenated alkenyl groups, for example, perfluoroalkenyl groups such as a perfluorovinyl group, a perfluoroallyl group, and a perfluorobutenyl group, and perchloroalkenyl groups;
C3 to C30 cycloalkyl groups (CₙH₂ₙ₋₁: n=3 to 30);
C3 to C30 perhalogenated cycloalkyl groups, such as perfluorocycloalkyl groups (CₙF₂ₙ₋₁: n=3 to 30) and perchlorocycloalkyl groups (CₙCl₂ₙ₋₁: n=3 to 30);
C3 to C30 cycloalkenyl groups, such as a cyclopentenyl group and a cyclohexenyl group;
C3 to C30 perhalogenated cycloalkenyl groups, such as perfluorocycloalkenyl groups and perchlorocycloalkenyl groups; and
C3 to C30 alkynyl groups, and
halogeno groups (e.g., F and Cl, preferably F),
A³ is selected from C2 to C30 alkylene groups (—CₙH₂ₙ—: wherein, n=2 to 30, preferably n=4 to 12) optionally having one or more substituents selected from the group (G1) and halogeno groups (e.g., F and Cl, preferably F),
regarding a benzene ring to which A¹ and an azomethine group are both bound, two adjacent carbon atoms of the benzene ring that are not bound with A¹ and the azomethine group are optionally connected via —C₄H₄— to form a naphthalene ring, and
the benzene ring and the optionally-formed naphthalene ring both optionally further have one or more substituents selected from the group (G1) and halogeno groups (e.g., F and Cl, preferably F)]; and
a β-diketonato ligand represented by Chemical Formula (II):

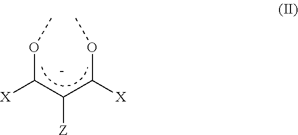

[wherein,
Xs represent substituents that are optionally the same as or different from each other and are selected from the group (G1), and
Z represents a fluorine atom, a chlorine atom, a bromine atom, an iodine atom, a cyano group, a methyl group, an ethyl group, a phenyl group, a hydrogen atom, or a deuterium atom].

The production method according to one embodiment of the present invention comprises preparing a ligand that is represented by the above-described Chemical Formula (I) and has two sets of azomethine groups, and dissolving this ligand in a first solvent to prepare a solution (1).

In one embodiment of the present invention, the first solvent is not particularly limited as long as it can dissolve the ligand that is represented by Chemical Formula (I) and has two sets of azomethine groups, and a metal complex phosphor intended by the present invention can be obtained; however, the first solvent is preferably a halogen-based solvent, particularly preferably a chlorine-based solvent. The first solvent preferably comprises, for example, dichloromethane, chloroform, carbon tetrachloride, or trichloroethylene.

The production method according to one embodiment of the present invention comprises preparing a rare earth metal complex that comprises a β-diketonato ligand represented by the above-described Chemical Formula (II) but does not comprise the ligand represented by Chemical Formula (I), and dissolving this rare earth metal complex in a second solvent to prepare a solution (2).

In one embodiment of the present invention, the second solvent is not particularly limited as long as it can dissolve the β-diketonato ligand represented by Chemical Formula (II) and a metal complex phosphor intended by the present invention can be obtained; however, the second solvent is preferably an ether-based solvent, more preferably a cyclic ether-based solvent. The second solvent preferably comprises, for example, tetrahydrofuran (THF), 2-methyltetrahydrofuran (2-MeTHF), or 4-methyltetrahydropyran (MTHP).

The production method according to one embodiment of the present invention comprises mixing the solution (1) and the solution (2).

In one embodiment of the present invention, a mixing method, a mixing apparatus, and the like to be used for mixing the solutions (1) and (2) are not particularly limited as long as a metal complex phosphor intended by the present disclosure can be obtained; however, it is preferred to slowly mix the solutions (1) and (2) such that larger complex crystals can be obtained.

More specifically, it is preferred to mix the solutions (1) and (2) in such a manner that a concentration increase rate represented by the following Equation (1) is 0.00875 (M/hr) or less:
(Amount of increase in concentration of metal complex phosphor)/(Time from start to completion of mixing) (1)

The concentration increase rate represented by Equation (1) is more preferably 0.006 (mol/hr) or less, still more preferably 0.004 (mol/hr) or less.

The following ligand concentration, addition rate, and the like can be utilized such that the above-described concentration increase rate is attained.

More specifically, for example, the concentration of the ligand represented by Chemical Formula (I) in the solution (1) may be, for example, 0.005 mol/L to 0.3 mol/L, 0.01 mol/L to 0.2 mol/L, or 0.03 mol/L to 0.1 mol/L.

For example, the concentration of the ligand represented by Chemical Formula (II) in the solution (2) may be 0.02 mol/L to 1.2 mol/L, 0.1 mol/L to 0.8 mol/L, or 0.2 mol/L to 0.6 mol/L.

The mixing is preferably performed by simultaneously adding the solution (1) at a rate of, for example, 0.1 mL/min to 20 mL/min, 0.5 mL/min to 10 mL/min, or 1 mL/min to 5 mL/min, and the solution (2) at a rate of, for example, 0.01 mL/min to 10 mL/min, 0.1 mL/min to 5 mL/min, or 0.5 mL/min to 2 mL/min. In this process, the temperature may be −25° C. to 50° C., 0° C. to 40° C., or 5° C. to 35° C. The time required for the mixing may be, for example, 30 minutes to 40 hours, 1 hour to 20 hours, or 4 hours to 10 hours.

The production method according to one embodiment of the present invention may comprise further mixing the solution (1) and the solution (2) in the presence of a third solvent.

In one embodiment of the present invention, the third solvent is not particularly limited as long as it not only has a low solubility of a complex obtained as a reaction product having the ligand represented by Chemical Formula (I) and the ligand represented by Chemical Formula (II) but also can adjust the solubility of a reaction solvent such that the complex is precipitated out of a reaction mixture, and a metal complex phosphor intended by the present invention can be obtained; however, the third solvent is preferably an alcohol-based solvent.

The number of carbon atoms of the alcohol-based solvent may be 1 to 4, or 1 to 3. Examples of the alcohol-based solvent comprise methanol, ethanol, propanol, isopropanol, butanol, isobutanol, sec-butanol, and t-butanol.

In one embodiment of the present invention, a crystal of a complex of a reaction product that is produced in advance may be allowed to exist at the time of mixing the solutions (1) and (2). By allowing such a crystal to exist, a complex that is larger and more suitable for the use as a phosphor can be obtained.

In One embodiment of the present invention, the production method may further comprise coating the surface of the resulting metal complex phosphor with an inorganic member or an organic member at 200° C. or lower. By coating the surface of the resulting metal complex phosphor with an inorganic member or an organic member, the durability of the metal complex phosphor can be further improved, so that a more preferred metal complex phosphor can be produced.

The temperature of the coating formation is preferably 200° C. or lower, more preferably 150° C. or lower, still more preferably 120° C. or lower, but may be 50° C. or higher, 70° C. or higher, or 90° C. or higher.

A method of the coating formation is not particularly limited as long as a metal complex phosphor intended by the present invention can be produced, and examples of the method comprise atomic layer deposition method (ALD), chemical vapor deposition method (CVD), and sol-gel method.

In another embodiment of the present invention, a novel metal complex phosphor that has an emission peak wavelength of 600 nm to 635 nm and comprises a rare earth metal complex is provided.

It is a rare earth metal complex comprising at least one chemical structure selected from the following Chemical Formulae (III) and (IV), in which the rare earth metal is 8-coordinate, and the metal complex phosphor has a particle size of 12 μm to 100 μm:

### Chemical Formula (III):

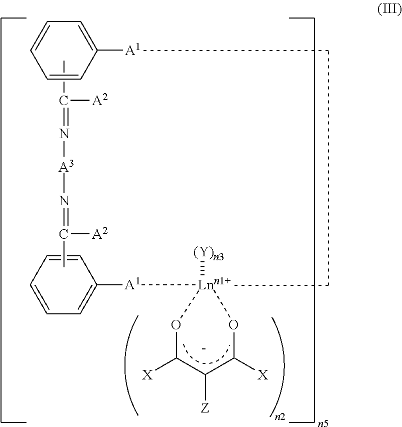 [0129] [wherein,
Ln represents a rare earth metal atom,
n1 represents 2 or 3,
regarding a β-diketonato ligand, Xs represent substituents that are optionally the same as or different from each other and are selected from the following group (G1):
aromatic groups, such as a phenyl group, a naphthyl group, and a biphenyl group;
perhalogenated aromatic groups, such as a perfluorophenyl group, a perfluoronaphthyl group, a perfluorobiphenyl group, a perchlorophenyl group, a perchloronaphthyl group, and a perchlorobiphenyl group;
heteroaromatic groups comprising at least one heteroatom selected from N, O, S, and the like in a ring;
linear or branched C1 to C30 alkyl groups (CₙH₂ₙ₊₁: n=1 to 30);
linear or branched C1 to C30 perhalogenated alkyl groups, such as perfluoroalkyl groups (CₙF₂ₙ₊₁: n=1 to 30) and perchloroalkyl groups (CₙCl₂ₙ₊₁: n=1 to 30);
linear or branched C3 to C30 alkenyl groups, such as a butenyl group;
linear or branched C3 to C30 perhalogenated alkenyl groups, for example, perfluoroalkenyl groups such as a perfluorovinyl group, a perfluoroallyl group, and a perfluorobutenyl group, and perchloroalkenyl groups;
C3 to C30 cycloalkyl groups (CₙH₂ₙ₋₁: n=3 to 30);
C3 to C30 perhalogenated cycloalkyl groups, such as perfluorocycloalkyl groups (CₙF₂ₙ₋₁: n=3 to 30) and perchlorocycloalkyl groups (CₙCl₂ₙ₋₁: n=3 to 30);
C3 to C30 cycloalkenyl groups, such as a cyclopentenyl group and a cyclohexenyl group;
C3 to C30 perhalogenated cycloalkenyl groups, such as perfluorocycloalkenyl groups and perchlorocycloalkenyl groups; and
C3 to C30 alkynyl groups,
Z represents a fluorine atom, a chlorine atom, a bromine atom, an iodine atom, a cyano group, a methyl group, an ethyl group, a phenyl group, a hydrogen atom, or a deuterium atom,
n2 represents an integer of 1 to 3,
Y is optionally at least one selected from a perchlorate ion, a nitrate ion, a carboxylate ion, and a halide ion,
n3 represents an integer of 0 to 2,
regarding a ligand having two sets of hydroxy groups or thiol groups and azomethine groups:
A¹ represents an OH group, an OD group, an SH group, or an SD group,
A² is selected from hydrogen, deuterium, C1 to C30 alkyl groups (—CₙH₂ₙ₊₁: wherein, n=1 to 30, preferably n=1 to 18, more preferably n=1 to 6, particularly preferably n=1 to 3), C3 to C30 cycloalkyl groups (—CₙH₂ₙ₋₁: wherein, n=3 to 30, preferably n=3 to 18, more preferably n=3 to 6, particularly preferably n=3), C1 to C30 perhalogenated alkyl groups (for example, —CₙF₂ₙ₊₁ and —CₙCl₂ₙ₊₁, preferably-CₙF₂ₙ₊₁: wherein, n=1 to 30, preferably n=1 to 18, more preferably n=1 to 6, particularly preferably n=1 to 3), and C3 to C30 perhalogenated cycloalkyl groups (for example, —CₙF₂ₙ₋₁ and —CₙCl₂ₙ₋₁, preferably-CₙF₂ₙ₋₁: wherein, n=3 to 30, preferably n=3 to 18, more preferably n=3 to 6, particularly preferably n=3), which groups optionally have one or more substituents selected from the above-described group (G1) and halogeno groups (e.g., F and Cl, preferably F),
A³ is selected from C2 to C30 alkylene groups (—CₙH₂ₙ₋: wherein, n=2 to 30, preferably n=4 to 12) optionally having one or more substituents selected from the above-described group (G1) and halogeno groups (e.g., F and Cl, preferably F),
regarding a benzene ring to which A¹ and an azomethine group are both bound, two adjacent carbon atoms of the benzene ring that are not bound with A¹ and the azomethine group are optionally connected via —C₄H₄— to form a naphthalene ring, and
the benzene ring and the optionally-formed naphthalene ring both optionally further have one or more substituents selected from the above-described group (G1) and halogeno groups (e.g., F and Cl, preferably F), and
n5 represents an integer of 2 or larger]; and

### Chemical Formula (IV):

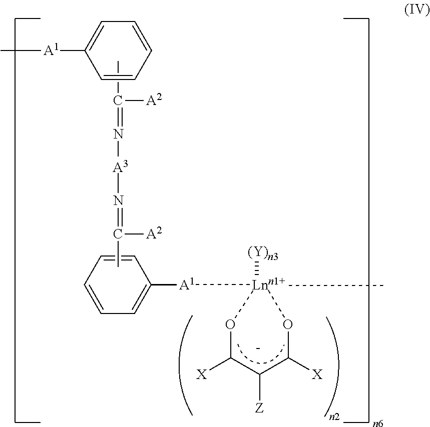 [0157] [wherein, all symbols have the same meaning as in Chemical Formula (III), except that n6 represents an integer of 1 or larger].

In Chemical Formulae (III) and (IV), the dotted line between A¹ and Ln and the dotted lines between O and Ln each represents a single coordinate bond. Accordingly, it is indicated that the β-diketonato ligand forms two coordinate bonds with a rare earth metal atom.

Meanwhile, the number of coordinate bonds that can be formed between Y and the rare earth metal atom may vary from 1 to 3; therefore, the space between Y and Ln is represented by a wide dotted line (hashed line), not a simple dotted line.

The ligand of Chemical Formula (I), which has both a hydroxy group (OH or OD) or a thiol group (SH or SD) (A¹) and an azomethine group (or Schiff base:—CA²═N—) and is comprised in the chemical structures of Chemical Formulae (III) and (IV), will now be further described.

The ligand of Chemical Formula (I) has two sets of hydroxy groups or thiol groups and azomethine groups.

The ligand of Chemical Formula (I) is coordinated to a rare earth metal atom via a hydroxy group (OH or OD) or a thiol group (SH or SD) represented by A¹.

The hydroxy groups or thiol groups (A¹) and the azomethine groups are both bound to a benzene ring, and the benzene ring may further form a naphthalene ring.

The positions of the hydroxy groups or thiol groups (A¹) and the azomethine groups are not particularly limited as long as an intended complex can be obtained, and may be any position of o-substitution, m-substitution, p-substitution, and the like; however, o-substitution is more preferred from the standpoint of emission characteristics.

The carbon atoms of the azomethine groups may have a substituent A². This A² is selected from hydrogen, deuterium, C1 to C30 alkyl groups (—CₙH₂ₙ₊₁: wherein, n=1 to 30, preferably n=1 to 18, more preferably n=1 to 6, particularly preferably n=1 to 3), C3 to C30 cycloalkyl groups (—CₙH₂ₙ₋₁: wherein, n=3 to 30, preferably n=3 to 18, more preferably n=3 to 6, particularly preferably n=3), C1 to C30 perhalogenated alkyl groups (for example, —CₙF₂ₙ₊₁ and —CₙCl₂ₙ₊₁, preferably —CₙF₂ₙ₊₁: wherein, n=1 to 30, preferably n=1 to 18, more preferably n=1 to 6, particularly preferably n=1 to 3), and C3 to C30 perhalogenated cycloalkyl groups (for example, —CₙF₂ₙ₋₁ and —CₙCl₂ₙ₋₁, preferably —CₙF₂ₙ₋₁: wherein, n=3 to 30, preferably n=3 to 18, more preferably n=3 to 6, particularly preferably n=3).

These C1 to C30 alkyl groups, C3 to C30 cycloalkyl groups, C1 to C30 perhalogenated alkyl groups, and C3 to C30 perhalogenated cycloalkyl groups of A² may each have one or more substituents selected from the following group (G1):
aromatic groups, such as a phenyl group, a naphthyl group, and a biphenyl group;
perhalogenated aromatic groups, such as a perfluorophenyl group, a perfluoronaphthyl group, a perfluorobiphenyl group, a perchlorophenyl group, a perchloronaphthyl group, and a perchlorobiphenyl group;
heteroaromatic groups comprising at least one heteroatom selected from N, O, S, and the like in a ring;
linear or branched C1 to C30 alkyl groups (CₙH₂ₙ₊₁: n=1 to 30);
linear or branched C1 to C30 perhalogenated alkyl groups, such as perfluoroalkyl groups (CₙF₂ₙ₊₁: n=1 to 30) and perchloroalkyl groups (CₙCl₂ₙ₊₁: n=1 to 30);
linear or branched C3 to C30 alkenyl groups, such as a butenyl group;
linear or branched C3 to C30 perhalogenated alkenyl groups, for example, perfluoroalkenyl groups such as a perfluorovinyl group, a perfluoroallyl group, and a perfluorobutenyl group, and perchloroalkenyl groups;
C3 to C30 cycloalkyl groups (CₙH₂ₙ₋₁: n=3 to 30);
C3 to C30 perhalogenated cycloalkyl groups, such as perfluorocycloalkyl groups (CₙF₂ₙ₋₁: n=3 to 30) and perchlorocycloalkyl groups (CₙCl₂ₙ₋₁: n=3 to 30);
C3 to C30 cycloalkenyl groups, such as a cyclopentenyl group and a cyclohexenyl group;
C3 to C30 perhalogenated cycloalkenyl groups, such as perfluorocycloalkenyl groups and perchlorocycloalkenyl groups; and
C3 to C30 alkynyl groups, and
halogeno groups (e.g., F and Cl, preferably F).

It is noted here that, although two kinds of substituent groups (G1) and (G) are described in the present specification, these groups are substantially the same, with the group (G) being more concisely described than the group (G1).

Further, a substituent comprised in the group (G1) that may be selected as a substituent of the C1 to C30 alkyl groups, C3 to C30 cycloalkyl groups, C1 to C30 perhalogenated alkyl groups, and C3 to C30 perhalogenated cycloalkyl groups of A² may be substituted with a substituent, such as a deuterium atom, a halogeno group (F, Cl, Br, or I), a hydroxy group, a nitro group, a sulfonyl group, a cyano group, a silyl group, a phosphonate group, a diazo group, a methoxy group, an amide group, a carboxyl group, or a mercapto group.

Taking into consideration the stability, the emission intensity, and the like of the rare earth metal complex or a transparent solid carrier containing (or enclosing) the rare earth metal complex, the group (G1) that may be selected as a substituent of the C1 to C30 alkyl groups, C3 to C30 cycloalkyl groups, C1 to C30 perhalogenated alkyl groups, and C3 to C30 perhalogenated cycloalkyl groups of A² preferably comprises C1 to C30 alkyl groups, C1 to C30 perhalogenated alkyl groups, aromatic groups, perhalogenated aromatic groups, heteroaromatic groups, and perhalogenated heteroaromatic groups, more preferably comprises C1 to C30 alkyl groups, C1 to C30 perfluoroalkyl groups, and C3 to C30 cycloalkyl groups, particularly preferably comprises a butyl group, a dodecyl group, and a cyclohexyl group.

The C1 to C30 alkyl groups, C3 to C30 cycloalkyl groups, C1 to C30 perhalogenated alkyl groups, and C3 to C30 perhalogenated cycloalkyl groups of A² may also comprise an ether structure, an ester structure, and/or a tertiary amine as a result of insertion of —O—, —COO—, or —N<, either singly or in a plural number, into a C—C single bond at an arbitrary position in the respective groups.

Further, as described above, A² may have an unsaturated group such as an alkenyl group, as long as A² does not form a conjugated system with an azomethine group.

A² is more preferably selected from hydrogen, deuterium, a methyl group, a trifluoromethyl group, and a cyclopropyl group.

The ligand of Chemical Formula (I) has two sets of A¹s and azomethine groups and, for example, as shown in the chemical structures of Chemical Formulae (III) and (IV), the A¹s may both form a coordinate bond with the same rare earth metal atom, or may form a coordinate bond with different rare earth metal atoms.

The chemical structures of Chemical Formulae (III) and (IV) can each be a bi- or multi-nuclear complex comprising two or more rare earth metal atoms. The chemical structure of Chemical Formula (III) represents a cyclic bi- or multi-nuclear complex formed by plural ligands that are connected via plural rare earth metal atoms in a cyclic manner, while the chemical structure of Chemical Formula (IV) represents a chain bi- or multi-nuclear complex formed by plural ligands that are connected via plural rare earth metal atoms in a chain-like manner.

In the ligand of Chemical Formula (I), the nitrogen atoms of the two azomethine groups are linked with each other by a linking group A³ (see, for example, Chemical Formulae (I), (III), and (IV)).

A³ is selected from C2 to C30 alkylene groups (—CₙH₂ₙ—, wherein n=2 to 30, preferably n=4 to 18, more preferably n=4 to 12).

A³ may have one or more substituents selected from the above-described group (G1) and halogeno groups (e.g., F and Cl, preferably F).

A substituent comprised in the group (G1) that may be selected as a substituent of A³ may be substituted with a substituent, such as a deuterium atom, a halogeno group (F, Cl, Br, or I), a hydroxy group, a nitro group, a sulfonyl group, a cyano group, a silyl group, a phosphonate group, a diazo group, a methoxy group, an amide group, a carboxyl group, or a mercapto group.

Considering the stability, the emission intensity, and the like of the rare earth metal complex or a transparent solid carrier comprising the rare earth metal complex, the group (G1) that may be selected as a substituent of A³ preferably comprises C1 to C30 alkyl groups, C1 to C30 perhalogenated alkyl groups, aromatic groups, perhalogenated aromatic groups, heteroaromatic groups, and perhalogenated heteroaromatic groups, more preferably comprises C1 to C30 alkyl groups, C1 to C30 perfluoroalkyl groups, and C3 to C30 cycloalkyl groups, particularly preferably comprises a butyl group, a dodecyl group, and a cyclohexyl group.

Further, A³ may also comprise an ether structure, an ester structure, and/or a tertiary amine as a result of insertion of —O—, —COO—, or —N<, either singly or in a plural number, into a C—C single bond at an arbitrary position in A³.

Moreover, as described above, A³ may have an unsaturated group such as an alkenyl group, as long as A³ does not form a conjugated system with an azomethine group.

Regarding the above-described ligand of Chemical Formula (I) and ligands having both a hydroxy group or a thiol group (A¹) and an azomethine group (—CA²=N—) in the chemical structures of Chemical Formulae (III) and (IV), a benzene ring that has both of A¹ and azomethine group and an optionally-formed naphthalene ring may further have one or more substituents selected from the above-described group (G1) and halogeno groups (e.g., F and Cl, preferably F).

A substituent comprised in the group (G1) that may be comprised in the benzene ring and the optionally-formed naphthalene ring may be substituted with a substituent, such as a deuterium atom, a halogeno group (F, Cl, Br, or I), a hydroxy group, a nitro group, a sulfonyl group, a cyano group, a silyl group, a phosphonate group, a diazo group, a methoxy group, an amide group, or a mercapto group.

Considering the stability, the emission intensity, and the like of the rare earth metal complex or a transparent solid carrier comprising the rare earth metal complex, the group (G1) comprising the substituent that may be comprised in the benzene ring and the naphthalene ring preferably comprises C1 to C30 alkyl groups, C1 to C30 perhalogenated alkyl groups, aromatic groups, perhalogenated aromatic groups, heteroaromatic groups, and perhalogenated heteroaromatic groups, more preferably comprises C1 to C30 alkyl groups, C1 to C30 perfluoroalkyl groups, and C3 to C30 cycloalkyl groups, particularly preferably comprises a butyl group, a dodecyl group, and a cyclohexyl group.

The β-diketonato ligand of Chemical Formula (II), which is comprised in the chemical structures of Chemical Formulae (III) and (IV), will now be described.

The β-diketonato ligand is a monovalent anion, and can be coordinated to a rare earth metal via two oxygen atoms.

The metal complex phosphor according to one embodiment of the present invention comprises a rare earth metal to which the β-diketonato ligand is coordinated, along with the above-described ligand having both a hydroxy group or a thiol group and an azomethine group.

The β-diketonato ligand has two Xs that may be the same as or different from each other.

These Xs are each selected from the following group (G1):
aromatic groups, such as a phenyl group, a naphthyl group, and a biphenyl group;
perhalogenated aromatic groups, such as a perfluorophenyl group, a perfluoronaphthyl group, a perfluorobiphenyl group, a perchlorophenyl group, a perchloronaphthyl group, and a perchlorobiphenyl group;
heteroaromatic groups comprising at least one heteroatom selected from N, O, S, and the like in a ring;
linear or branched C1 to C30 alkyl groups (CₙH₂ₙ₊₁: n=1 to 30);
linear or branched C1 to C30 perhalogenated alkyl groups, such as perfluoroalkyl groups (CₙF₂ₙ₊₁: n=1 to 30) and perchloroalkyl groups (CₙCl₂ₙ₊₁: n=1 to 30);
linear or branched C3 to C30 alkenyl groups, such as a butenyl group;
linear or branched C3 to C30 perhalogenated alkenyl groups, for example, perfluoroalkenyl groups such as a perfluorovinyl group, a perfluoroallyl group, and a perfluorobutenyl group, and perchloroalkenyl groups;
C3 to C30 cycloalkyl groups (CₙH₂ₙ₋₁: n=3 to 30);
C3 to C30 perhalogenated cycloalkyl groups, such as perfluorocycloalkyl groups
(CₙF₂ₙ₋₁: n=3 to 30) and perchlorocycloalkyl groups (CₙCl₂ₙ₋₁: n=3 to 30);
C3 to C30 cycloalkenyl groups, such as a cyclopentenyl group and a cyclohexenyl group;
C3 to C30 perhalogenated cycloalkenyl groups, such as perfluorocycloalkenyl groups and perchlorocycloalkenyl groups; and
C3 to C30 alkynyl groups.

Further, a substituent comprised in the group (G1) that may be selected as X may be substituted with a substituent, such as a deuterium atom, a halogeno group (F, Cl, Br, or I), a hydroxy group, a nitro group, an amino group, a sulfonyl group, a cyano group, a silyl group, a phosphonate group, a diazo group, or a mercapto group.

The group (G1) that may be selected as X preferably comprises perfluoroalkyl groups (CₙF₂ₙ₊₁: n=1 to 30), a phenyl group, a naphthyl group, and a phenanthryl group, more preferably comprises perfluoroalkyl groups (CₙF₂ₙ₊₁: n=1 to 6), a phenyl group, and a naphthyl group, particularly preferably comprises perfluoroalkyl groups (CₙF₂ₙ₊₁: n=1 to 3), a phenyl group, and a naphthyl group.

In the β-diketonato ligand, Z preferably comprises a fluorine atom, a chlorine atom, a bromine atom, an iodine atom, a cyano group, a methyl group, an ethyl group, a phenyl group, a hydrogen atom, or a deuterium atom, particularly preferably comprises a hydrogen atom, a deuterium atom, or a fluorine atom.

Examples of a rare earth element (for example, represented by Ln in Chemical Formulae (III) and (IV)) relating to the metal complex phosphor according to one embodiment of the present invention comprise the lanthanum series elements, such as La, Ce, Pr, Nd, Pm, Sm, Eu, Gd, Tb, Dy, Ho, Er, Tm, Yb, and Lu, among which Eu, Sm, and Dy are preferred. These rare earth elements may be used singly, or in combination of two or more kinds thereof.

The metal complex phosphor according to one embodiment of the present invention may further comprise other ligand. This other ligand is not particularly limited as long as a metal complex phosphor intended by one embodiment of the present invention can be obtained, and it is, for example, an anion selected from a perchlorate ion, a nitrate ion, a carboxylate ion, and halide ions. The other ligand is represented by, for example, Y in Chemical Formulae (III) and (IV). The other ligand is preferably selected from a carbonate ion, a sulfate ion, and trifluoromethanesulfonate ion.

Regarding the metal complex phosphor according to one embodiment of the present invention that comprises the chemical structures of Chemical Formulae (III) and (IV):
n1 representing a positive charge of the rare earth element is 2 or 3, preferably 3;
n2 representing the number of β-diketonato ligands is 1 to 3;
n3 representing the number of other ligands is any number of 0 to 2;
n4 representing the number of ligands having an azomethine group is 1 to 3;
the coordination number of the rare earth metal is 3 to 11;
n2 and n3 are preferably a combination satisfying n2+n3=3;
n2 is more preferably 3, and n3 is more preferably 0;
n5 representing the number of plural ligands connected in a cyclic manner is preferably an integer of 2 or larger, more preferably 2 to 8; and
n6 representing the number of plural ligands connected in a chain-like manner is desirably any integer, more preferably 3 or larger.

In one embodiment of the present invention, a novel trivalent rare earth metal complex phosphor that comprises both a β-diketonato ligand and a ligand having a hydroxy group or a thiol group and an azomethine group (Schiff base) can be provided.

This novel trivalent rare earth metal complex phosphor can be preferably used as a wavelength conversion member, and is more preferably capable of absorbing light of the ultraviolet to blue region and emitting a light.

The trivalent rare earth metal complex phosphor still more preferably has an excitation wavelength range in a broader visible light region, with a higher absorptivity, a lower reflectance, and a higher brightness.

In the metal complex phosphor according to one embodiment of the present invention, by changing the structures of its ligands and/or the type and the like of the rare earth atom, the absorption wavelength range can be modified, so that the emission wavelength range can be modified. Therefore, the metal complex phosphor according to one embodiment of the present invention can provide a novel wavelength conversion material having various properties.

The metal complex phosphor according to one embodiment of the present invention can have a larger particle size and a longer durability. The present invention can provide a transparent solid carrier (e.g., a phosphor sheet) containing (or enclosing) this metal complex phosphor, as well as a light emitting device comprising such a transparent solid carrier.

The metal complex phosphor according to one embodiment of the present invention preferably has an average particle size of 5 μm to 50 μm. The average particle size of the metal complex phosphor is more preferably 7 μm to 40 μm, still more preferably 10 μm to 30 μm, most preferably 13 μm to 25 μm. When the average particle size of the metal complex phosphor is 5 μm to 50 μm, a superior durability can be obtained.

The metal complex phosphor according to one embodiment of the present invention preferably has a median (50%) particle size of 12 μm to 100 μm. The median particle size of the metal complex phosphor is more preferably 13 μm to 90 μm, still more preferably 14 μm to 80 μm, yet still more preferably 15 μm to 70 μm, most preferably 20 μm to 60 μm. When the median particle size of the metal complex phosphor is 12 μm to 100 μm, a superior durability can be obtained.

The metal complex phosphor according to one embodiment of the present invention preferably has a BET specific surface area of 0.1 m²/g to 2.30 m²/g. The BET specific surface area of the metal complex phosphor is more preferably 0.2 m²/g to 2.00 m²/g, still more preferably 0.3 m²/g to 1.80 m²/g, yet still more preferably 0.3 m²/g to 1.50 m²/g, most preferably 0.4 m²/g to 1.20 m²/g. When the BET specific surface area of the metal complex phosphor is 0.1 m²/g to 2.30 m²/g, a superior durability can be obtained.

The metal complex phosphor according to one embodiment of the present invention has a specific gravity of preferably 1.570 g/cm³ to 2.000 g/cm³, more preferably 1.575 g/cm³ to 2.000 g/cm³. When the specific gravity of the metal complex phosphor is 1.570 g/cm³ to 2.000 g/cm³, the metal complex phosphor is a compact polymer due to such a high specific gravity, so that a superior durability can be obtained.

A method of producing the metal complex phosphor according to one embodiment of the present invention (more specifically, for example, a complex comprising the chemical structures of Chemical Formulae (III) and (IV)) is not particularly limited as long as the metal complex phosphor can be obtained; however, it is preferred to employ the above-described production method.

The metal complex phosphor according to one embodiment of the present invention preferably has a coating formed of an inorganic member or an organic member on the outside. At least a portion of the periphery of the metal complex phosphor may be covered with the coating. Examples of the inorganic member comprise SiO₂ and Al₂O₃, and the inorganic member is preferably SiO₂ or Al₂O₃. Examples of the organic member comprise resin members made of a silicone resin, an epoxy resin, a (meth)acrylic resin or the like, and the organic member is preferably a resin member made of a silicone resin, an epoxy resin, or a (meth)acrylic resin, or the like.

When the metal complex phosphor according to one embodiment of the present invention has a coating formed of an inorganic member or an organic member on the outside, the metal complex phosphor exhibits a higher durability (emission brightness retention rate).

The periphery of the metal complex phosphor may also be covered with a resin member made of a silicone resin, an epoxy resin, a (meth)acrylic resin, or the like, or with an inorganic member made of SiO₂, Al₂O₃, or the like. By covering the metal complex phosphor with such a member, the durability of the metal complex phosphor can be improved.

The metal complex phosphor according to one embodiment of the present invention can be used as various optical functional materials, such as light-emitting auxiliary materials, optical lenses, fluorescent probes, and security inks.

Further, by incorporating the metal complex phosphor according to one embodiment of the present invention into a transparent solid carrier, the transparent solid carrier can be used in various optical functional materials in the same manner. By incorporating the metal complex phosphor into a transparent solid carrier, for example, the ease of handling, the stability, and the moldability are improved, which is preferred.

Accordingly, the present invention provides: a transparent solid carrier for an optical functional material, which comprises the metal complex phosphor according to one embodiment of the present invention; and a method of producing a transparent solid carrier for an optical functional material, which method comprises incorporating the metal complex phosphor according to one embodiment of the present invention into a transparent solid carrier.

The transparent solid carrier according to one embodiment of the present invention is not particularly limited as long as it is transparent and solid and can be used as a carrier of the metal complex phosphor according to one embodiment of the present invention. For example, a transparent polymer matrix or a transparent glass can be used.

Examples of the transparent polymer matrix comprise polymethyl methacrylates (PMMAs), fluorine-containing polymethacrylates, polyacrylates, fluorine-containing polyacrylates, polystyrenes, polyolefins (e.g., polyethylenes, polypropylenes, and polybutenes), fluorine-containing polyolefins, polyvinyl ethers, fluorine-containing polyvinyl ethers, polyvinyl acetates, polyvinyl chlorides, and copolymers thereof, as well as celluloses, polyacetals, polyesters, polycarbonates, epoxy resins, polyamide resins, polyimide resins, polyurethanes, NAFION, petroleum resins, rosin, silicon resins, and thiol resins.

As the transparent polymer matrix, it is preferred to use a polymethyl methacrylate, a fluorine-containing polymethacrylate, a polyacrylate, a fluorine-containing polyacrylate, a polystyrene, a polyolefin, a polyvinyl ether, or a copolymer thereof, or a silicon resin, a thiol resin, an epoxy resin, or the like.

These transparent polymer matrices may be used singly, or in combination of two or more kinds thereof.

In one embodiment of the present invention, a phosphor-containing transparent solid carrier in which the above-described metal complex phosphor is comprised in a transparent solid carrier (e.g., a resin or a glass) can be provided. When the transparent solid carrier is in the form of a sheet, the sheet-form transparent solid carrier comprising the above-described metal complex phosphor as a whole is also referred to as “phosphor sheet”.

Accordingly, in one embodiment of the present invention, a phosphor sheet comprising the above-described metal complex phosphor in a resin (or a polymer) or a glass can be provided.

In one embodiment of the present invention, the phosphor sheet may further comprise quantum dots having an emission peak wavelength of 515 nm to 540 nm. When the phosphor sheet comprises such quantum dots, the phosphor sheet can exert an advantageous effect that it has a wider color gamut.

The phosphor sheet may be formed of a single layer or two or more layers, and the number of layers comprised in the phosphor sheet can be selected as appropriate.

In one embodiment of the present invention, the phosphor sheet may comprise the quantum dots and the metal complex phosphor in a single layer. In this case, the phosphor sheet can be further reduced in thickness.

Alternatively, in one embodiment of the present invention, the phosphor sheet may comprise plural layers, comprising a first layer comprising the quantum dots, and a second layer comprising the metal complex phosphor. The second layer preferably comprises the metal complex phosphor and quantum dots having an emission peak wavelength of 600 nm to 650 nm. In this case, the durability can be further improved.

In the present disclosure, the “quantum dots” refer to semiconductor particles that have a particle size of, for example, 10 nm or less, and exhibit a quantum size effect, and the quantum dots are not particularly limited as long as a phosphor sheet intended by the present disclosure can be obtained.

The “quantum size effect” refers to a phenomenon in which a valence band and a conduction band that are each regarded as continuous in bulk particles become discrete when the particle size is reduced to the nanoscale, and the band-gap energy varies with the particle size.

Quantum dots are capable of absorbing light and converting its wavelength into a light corresponding to their band-gap energy. White light emitting devices utilizing emission of such quantum dots have been proposed and, for example, such quantum dots can be utilized in the present disclosure as well. For example, those quantum dots described in JP 2012-212862 A, JP 2010-177656 A, WO 2018/159699, WO 2019/160094, WO 2020/162622, WO 2022/191032, and WO 2022/191032 can be utilized.

The metal complex phosphor according to one embodiment of the present invention has a reflectance of preferably 50% or less, more preferably 40 to 1%, particularly preferably 30 to 1%, for a 450-nm incident light.

The metal complex phosphor according to one embodiment of the present invention has a reflectance of preferably 60% or more, more preferably 70 to 120%, particularly preferably 80 to 120%, for a 550-nm incident light.

It is noted here that these reflectance values are relative values, taking the reflectance of calcium phosphate as 100% (standard).

The metal complex phosphor according to one embodiment of the present invention exhibits low absorption of green light; therefore, it is preferred to combine the metal complex phosphor with a green phosphor since this further improves the brightness and gives a higher efficiency.

The term “green phosphor” or “green quantum dot” used herein refers to a phosphor having a fluorescence peak wavelength in a range of 500 nm to 600 nm.

Examples of such a green phosphor or green quantum dot comprise β-sialon-based phosphors (e.g., (Si,Al)₃ (O,N)₄: Eu), SAE-based phosphors (e.g., Sr₄Al₁₄O₂₅: Eu), chlorosilicate-based phosphors (e.g., Ca₈MgSi₄O₁₆Cl₂: Eu), thiogallate-based phosphors (e.g., SrGa₂S₄: Eu), quantum dots having a perovskite structure (e.g., (Cs,FA,MA) (Pb,Sn) (F,Cl,Br,I)₃, wherein FA and MA represent formamidinium and methylammonium, respectively), Group II-VI quantum dots (e.g., CdSe), Group III-V quantum dots (e.g., InP), and quantum dots having a chalcopyrite structure (e.g., (Ag,Cu) (In,Ga) (S,Se)₂).

The metal complex phosphor according to one embodiment of the present invention has a relative emission intensity, which is described below, of preferably 5% or more, more preferably 50% or more, still more preferably 100% or more, particularly preferably 110% or more. The relative emission intensity is a value measured when the metal complex phosphor is excited with a 450-nm excitation light.

The reflectance of the metal complex phosphor according to one embodiment of the present invention and that of a transparent solid carrier comprising the metal complex phosphor for a 450-nm incident light can be lower than the reflectance of a conventional rare earth metal complex phosphor for a 450-nm incident light; therefore, as compared to a conventional rare earth metal complex phosphor, the metal complex phosphor according to one embodiment of the present invention and the transparent solid carrier comprising the same can have a higher wavelength conversion efficiency for a 450-nm incident light. Further, more preferably, a light emitting device having a high emission efficiency can be obtained by using the metal complex phosphor according to one embodiment of the present invention.

Under a high-temperature and high-humidity condition, the metal complex phosphor according to one embodiment of the present invention has a durability of, for example, 300 hours or longer, preferably 500 hours or longer, more preferably 750 hours or longer, still more preferably 1,000 hours or longer, particularly preferably 1,500 hours or longer, in a state of being comprised in a transparent solid carrier.

Under a high-temperature and high-humidity condition (e.g., 60° C. and 90% RH), the metal complex phosphor according to one embodiment of the present invention has a higher durability of 300 hours or longer in a state of being comprised in a transparent solid carrier.

The light emitting device according to one embodiment of the present invention is constituted by combining the metal complex phosphor according to one embodiment of the present invention or a transparent solid carrier comprising the same with a light emitting diode or a laser diode.

The metal complex phosphor according to one embodiment of the present invention or the transparent solid carrier comprising the same can be arranged, for example, on an upper surface (light-emitting surface) or a side surface (light incident surface of the light emitting diode) of a light guide plate, in a cup of the light emitting device, or in a resin sealing the light emitting diode, in the same manner as a conventional phosphor.

The light emitting diode or laser diode preferably emits a light having substantially the same wavelength as a peak wavelength of an excitation spectrum that corresponds to the f-f transition of a central ion or the absorption of a ligand in the metal complex phosphor according to one embodiment of the present invention. As the light emitting diode or laser diode, for example, a nitride semiconductor light emitting element that comprises an In-containing nitride semiconductor layer as a light emitting layer can be used. The emission peak wavelength of this nitride semiconductor light emitting element can be adjusted by modifying the In content of the light emitting layer.

As described below in the section of Examples, the metal complex phosphor according to one embodiment of the present invention can more preferably exhibit an excitation spectrum in a broad ultraviolet to visible light region. In such a case, it is also possible to constitute a light emitting device using plural light emitting elements that correspond to the respective wavelengths.

In one embodiment of the present invention, a light emitting device that comprises the above-described phosphor sheet and a light emitting element having an emission peak wavelength of 380 nm to 490 nm can be provided. By incorporating a light emitting element having an emission peak wavelength of 380 nm to 490 nm, a wider color gamut can be obtained.

The light emitting device according to one embodiment of the present invention can be used as, for example, a general lighting device, signal device, or display device.

More specific examples of the light emitting device comprise brake lamps of automobiles, door indicator lamps, and decorative panels installed in stores and the like, as well as backlights, side lights, and the like for display devices such as personal computers, mobile terminals, mobile phones, smartphones, and tablet computers.

The present invention encompasses the following embodiments.

### (Note 1)

A method of producing a metal complex phosphor having an emission peak wavelength of 600 nm to 635 nm, the method comprising:
preparing a ligand that is represented by the following Chemical Formula (I) and comprises two sets of azomethine groups, and dissolving this ligand in a first solvent to prepare a solution (1);
preparing a rare earth metal complex that comprises a β-diketonato ligand represented by the following Chemical Formula (II) but does not comprise the ligand represented by Chemical Formula (I), and dissolving this rare earth metal complex in a second solvent to prepare a solution (2); and
mixing the solution (1) and the solution (2):

### Chemical Formula (I):

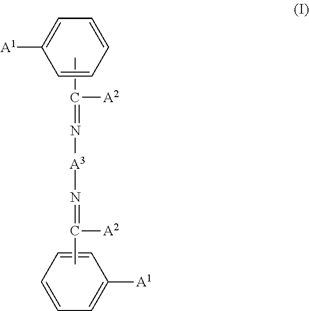 [0283] [wherein,
A¹ represents an OH group, an OD group, an SH group, or an SD group,
A² is selected from hydrogen, deuterium, C1 to C30 alkyl groups, C3 to C30 cycloalkyl groups, C1 to C30 perhalogenated alkyl groups, and C3 to C30 perhalogenated cycloalkyl groups, which groups optionally have one or more substituents selected from the following group (G):
aromatic groups;
perhalogenated aromatic groups;
heteroaromatic groups comprising at least one heteroatom in a ring;
linear or branched C1 to C30 alkyl groups;
linear or branched C1 to C30 perhalogenated alkyl groups;
linear or branched C3 to C30 alkenyl groups;
linear or branched C3 to C30 perhalogenated alkenyl groups;
C3 to C30 cycloalkyl groups;
C3 to C30 perhalogenated cycloalkyl groups;
C3 to C30 cycloalkenyl groups;
C3 to C30 perhalogenated cycloalkenyl groups; and
C3 to C30 alkynyl groups, and halogeno groups,
A³ is selected from C2 to C30 alkylene groups optionally having one or more substituents selected from the group (G) and halogeno groups,
regarding a benzene ring to which A¹ and an azomethine group are both bound, two adjacent carbon atoms of the benzene ring that are not bound with A¹ and the azomethine group are optionally connected via —C₄H₄— to form a naphthalene ring, and
the benzene ring and the optionally-formed naphthalene ring optionally further have one or more substituents selected from the group (G) and halogeno groups]; and

### Chemical Formula (II):

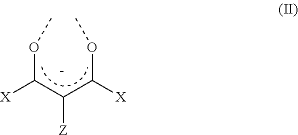 [0302] [wherein,
Xs represent substituents that are optionally the same as or different from each other and are selected from the group (G), and
Z represents a fluorine atom, a chlorine atom, a bromine atom, an iodine atom, a cyano group, a methyl group, an ethyl group, a phenyl group, a hydrogen atom, or a deuterium atom].

### (Note 2)

The method of producing a metal complex phosphor according to Note 1, the method comprising mixing the solution (1) and the solution (2) such that a concentration increase rate represented by the following Equation (1) is 0.00875 (M/hr) or less:
(Amount of increase in concentration of metal complex phosphor)/(Time from start to completion of mixing) (1)

### (Note 3)

The method of producing a metal complex phosphor according to Note 1 or 2,
wherein
the first solvent comprises a halogen-based solvent, and
the second solvent comprises an ether-based solvent.

### (Note 4)

The method of producing a metal complex phosphor according to any one of Notes 1 to 3, the method comprising further mixing the solution (1) and the solution (2) in the presence of a third solvent.

### (Note 5)

The method of producing a metal complex phosphor according to Note 4, wherein the third solvent comprises an alcohol-based solvent.

### (Note 6)

The method of producing a metal complex phosphor according to any one of Notes 1 to 5, the method further comprising coating the surface of the metal complex phosphor with an inorganic member or an organic member at 200° C. or lower.

### (Note 7)

A metal complex phosphor, comprising a rare earth metal complex and having a D50 particle size of 12 μm to 100 μm,
wherein
the rare earth metal complex comprises at least one chemical structure selected from the following Chemical Formulae (III) and (IV),
the rare earth metal is 8-coordinate, and
the metal complex phosphor has an emission peak wavelength of 600 nm to 635 nm:

### Chemical Formula (III):

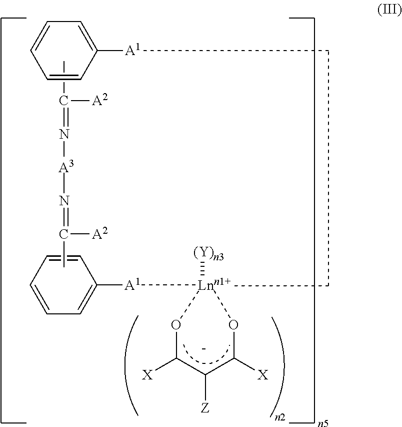 [0320] [wherein,
Ln represents a rare earth metal atom,
n1 represents 2 or 3,
regarding a β-diketonato ligand, Xs represent substituents that are optionally the same as or different from each other and are selected from the following group (G):
aromatic groups;
perhalogenated aromatic groups;
heteroaromatic groups comprising at least one heteroatom in a ring;
linear or branched C1 to C30 alkyl groups;
linear or branched C1 to C30 perhalogenated alkyl groups;
linear or branched C3 to C30 alkenyl groups;
linear or branched C3 to C30 perhalogenated alkenyl groups;
C3 to C30 cycloalkyl groups;
C3 to C30 perhalogenated cycloalkyl groups;
C3 to C30 cycloalkenyl groups;
C3 to C30 perhalogenated cycloalkenyl groups; and
C3 to C30 alkynyl groups,
Z represents a fluorine atom, a chlorine atom, a bromine atom, an iodine atom, a cyano group, a methyl group, an ethyl group, a phenyl group, a hydrogen atom, or a deuterium atom,
n2 represents an integer of 1 to 3,
Y is optionally at least one selected from a perchlorate ion, a nitrate ion, a carboxylate ion, and a halide ion,
n3 represents an integer of 0 to 2,
regarding a ligand that comprises two sets of azomethine groups:
A¹ represents an OH group, an OD group, an SH group, or an SD group,
A² is selected from hydrogen, deuterium, C1 to C30 alkyl groups, C3 to C30 cycloalkyl groups, C1 to C30 perhalogenated alkyl groups, and C3 to C30 perhalogenated cycloalkyl groups, which groups optionally have one or more substituents selected from the group (G) and halogeno groups,
A³ is selected from C2 to C30 alkylene groups optionally having one or more substituents selected from the group (G) and halogeno groups,
regarding a benzene ring to which A¹ and an azomethine group are both bound, two adjacent carbon atoms of the benzene ring that are not bound with A¹ and the azomethine group are optionally connected via —C₄H₄— to form a naphthalene ring,
the benzene ring and the optionally-formed naphthalene ring optionally further have one or more substituents selected from the group (G) and halogeno groups, and
n5 represents an integer of 2 or larger]; and

### Chemical Formula (IV):

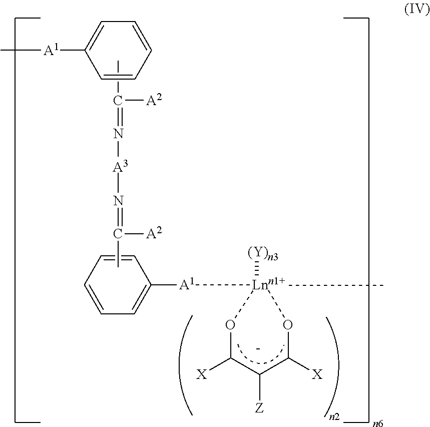 [0348] [wherein, all symbols have the same meaning as in Chemical Formula (III), except that n6 represents an integer of 1 or larger].

### (Note 8)

The metal complex phosphor according to Note 7, having a specific gravity of 1.570 g/cm³ to 2.000 g/cm³.

### (Note 9)

The metal complex phosphor according to Note 7 or 8, comprising a coating formed of an inorganic member or an organic member on the outside.

### (Note 10)

A phosphor sheet, comprising the metal complex phosphor according to any one of Notes 7 to 9 in a resin or a glass.

### (Note 11)

The phosphor sheet according to Note 10, comprising quantum dots having an emission peak wavelength of 515 nm to 540 nm.

### (Note 12)

The phosphor sheet according to Note 11, comprising the quantum dots and the metal complex phosphor in a single layer.

### (Note 13)

The phosphor sheet according to Note 11 or 12, comprising:
a first layer that comprises the quantum dots; and
a second layer that comprises the metal complex phosphor and quantum dots having an emission peak wavelength of 600 nm to 650 nm.

### (Note 14)

A light emitting device, comprising:
the phosphor sheet according to any one of Notes 10 to 13; and
a light emitting element having an emission peak wavelength of 380 nm to 490 nm.

### EXAMPLES

The present invention will now be described more concretely and in more detail by way of Examples and Comparative Examples; however, the below-described Examples merely represent modes of the present invention, and the present invention is not limited by these Examples at any rate.

In the descriptions of Examples, unless otherwise specified, those parts where a solvent is not taken into account are based on parts by mass or % by weight.

Components used in the present Examples are shown below.

### (I) Ligand Having Hydroxy Groups or Thiol Groups and Azomethine Groups

(I-1) N,N′-bis(p-hydroxyphenylacetylidene)-1,4-butylenediamine (H₂1,4-acebn) [HO—C₆H₄—C(CH₃)═N—(CH₂)₄—N═C(CH₃)—C₆H₄—OH] (benzene rings are both ortho-substituted)
   (II)β-diketonato Ligand
(II-1) ligand based on benzoyltrifluoroacetone (btfa) [CF₃—CO—CH₂—CO—C₆H₅]
A β-diketonato ligand that is a monovalent anion is hereinafter also referred to as “btfa-”.

### Example 1: Synthesis of Complex Comprising Europium Coordinated with Both H₂1,4-Acebn and Btfa⁻

A THF solution was obtained by adding 113.7 g of a white solid powder [EuIII(BTFA)₃ (H₂O)₂)] to 390 ml of THF.

A dichloromethane solution was obtained by adding a solid powder (a4) N,N′-bis(hydroxyphenylacetylidene)-1,4-butanediamine (H₂1,4-acebn) [HO—C₆H₄—C(CH₃)═N—(CH₂)₄—N═C(CH₃)—C₆H₄—OH: 44.3 g] (benzene rings are both ortho-substituted) to 1,560 mL of dichloromethane.

To 1,950 mL of ethanol, 7.9 g of a complex to be obtained in Example 1 (a total of 5% by mass of the above-described raw materials), which had been synthesized in advance and recrystallized, was added.

The above-obtained THF solution and dichloromethane solution were added to the ethanol comprising crystals of the complex over a period of 8 hours at room temperature, and the resultant was continuously stirred for a day. The resulting precipitated solid was filtered. Dichloromethane was removed by vacuum distillation, whereby a complex of Example 1 was obtained. The production method and the physical properties of the complex of Example 1 are shown in Table 1. It can be understood that the complex of Example 1 had a larger particle size than the below-described complex of Comparative Example 1.

### Comparative Example 1: Synthesis of Complex Comprising Europium Coordinated with Both H₂1,4-Acebn and Btfa⁻

A dispersion was obtained by dispersing 26.3 g of a white solid powder [EuIII(BTFA)₃ (H₂O)₂)] in 450 ml of dichloromethane.

A solid powder of (a4) N,N′-bis(hydroxyphenylacetylidene)-1,4-butanediamine (H₂1,4-acebn) [HO—C₆H₄—C(CH₃)═N—(CH₂)₄—N═C(CH₃)—C₆H₄—OH: 10.2 g] (benzene rings are both ortho-substituted) was directly added to the above-obtained dispersion at once, and the resultant was stirred at room temperature for a day. The resulting precipitated solid was filtered. Dichloromethane was removed by vacuum distillation to obtain a yellow product. This product was washed with cold ethanol solvent, and ethanol was subsequently removed by vacuum distillation, whereby a complex of Comparative Example 1 was obtained. The production method and the physical properties of the complex of Comparative Example 1 are shown in Table 1.

TABLE 1

| | | | | Comparative | |
|---|---|---|---|---|---|
| | | Example 1 | | Example 1 | |
| Average particle size | | 18 | μm | 4 | μm |
| Median particle | | 45.0 | μm | 11.6 | μm |
| size D50 | | | | | |
| σlog | | 0.308 | | 0.287 | |
| BET specific | | 0.51 | m²/g | 2.39 | m²/g |
| surface area | | | | | |
| True specific gravity | | 1.575 | g/cm³ | 1.568 | g/cm³ |
| Powder chromaticity | x | 0.674 | | 0.673 | |
| | y | 0.326 | | 0.327 | |
| Relative emission | | 118% | | 100% | |
| intensity | | | | | |
| Reflectance | 450 nm | 8.0% | | 45.4% | |
| C | | 53.7% by weight | | 53.1% by weight | |
| N | | 2.54% by weight | | 2.55% by weight | |
| H | | 3.59% by weight | | 3.69% by weight | |
| Eu | | 13.2% by weight | | 13.4% by weight | |
| Decomposition | TG/DTA | 230° | C. | 230° | C. |
| temperature | | | | | |

The physical properties were measured as follows.

The average particle size was measured in accordance with the FSSS method using Fisher Sub-Sieve Sizer Model 95 manufactured by Thermo Fisher Scientific, Inc.

As the median particle size, the cumulative 50% particle size (D50 particle size) from the small side in a volume-based particle size distribution was measured using a laser diffraction-type particle size distribution analyzer (MS-2000 (product name), manufactured by Malvern Panalytical Ltd.).

The σlog is a standard deviation of log-normal distribution.

The BET specific surface area was measured using an automatic specific surface area analyzer (MACSORB (trade name), manufactured by Mountech Co., Ltd.). The BET specific surface area was measured by a single-point BET method using nitrogen gas.

As the true specific gravity, the true density was measured by a gas substitution method using a true density analyzer (AccuPyc, manufactured by Micromeritics Instrument Corporation).

The relative emission intensity was measured at room temperature (25° C.±5° C.) using a quantum efficiency measurement system (trade name: QE-2000, manufactured by Otsuka Electronics Co., Ltd.) by irradiating each phosphor with a light having an excitation wavelength of 450 nm. The relative emission intensity was calculated taking the emission intensity of the metal complex phosphor of Comparative Example 1 as 100%.

The reflectance was measured using a spectrofluorometer F-4500. As a reflectance standard, CaHPO₄ was used.

Using a scanning electron microscope (SEM), an SEM image was taken at a voltage of 5.0 kV. The magnification was ×1,000 in Examples and ×2,000 in Comparative Examples.

Elements (C, N, and H) were analyzed using an element analyzer 2400II (model number) manufactured by PerkinElmer Co., Ltd.

An element (Eu) was analyzed using AVIO 500 (model number) manufactured by PerkinElmer Co., Ltd. It is noted here that, considering the analysis error of Eu, the value of N/Eu is believed to be 0.19 to 0.21.

The TG/DTA was measured using a thermogravimetric differential thermal analyzer TD/DTA 6300 (model number) manufactured by Hitachi High-Tech Science Corporation. A 2-g sample was placed in an A1 pan and heated from 30° C. to 350° C. at a temperature increase rate of 5° C./min to measure a TG/DTA chart. The temperature at which the weight was reduced was defined as the decomposition temperature.

The IR was measured by ATR method using a Fourier transform infrared spectrophotometer FT-IR (model is 5, manufactured by Thermo Fisher Scientific K.K.).

### Production of Phosphor Sheet of Example 2 Comprising Complex of Example 1, and Phosphor Sheet of Comparative Example 2 Comprising Complex of Comparative Example 1

Phosphor sheets were each produced using the complex of Example 1 and the complex of Comparative Example 1. A resin composition was obtained by mixing 0.15 g of each complex, 3.5 g of an acrylic resin, 1.5 g of a thiol resin, 0.3 g of a scattering agent (silicone resin powder), and 0.05 g of a photoinitiator. The thus obtained resin composition was made into the form of a sheet, and barrier films were arranged above and below this resin composition sheet to sandwich the sheet. This sheet was irradiated with UV light at room temperature to UV-cure the resin of the sheet, whereby a phosphor sheet of Example 2 and a phosphor sheet of Comparative Example 2 were each obtained. The thickness of the resin layer (sheet) (excluding the barrier films) was 75 μm.

With regard to the phosphor sheet of Example 2 and the phosphor sheet of Comparative Example 2, the durability in operation at room temperature (500 hours and 1,000 hours), the durability in operation at 60° C. and 90% humidity (500 hours and 1,000 hours), and the durability in storage at 60° C. and 90% humidity (500 hours and 1,000 hours) were evaluated. The results thereof are shown in Table 2. From Table 2, it can be understood that the phosphor sheet of Example 2 had a higher brightness retention rate. Particularly, it can be understood that the phosphor sheet of Example 2 has a higher durability since it exhibited a higher brightness retention rate at 60° C. and 90% humidity.

The durability of each phosphor sheet was evaluated in the following manner.

### (Operation Test at Room Temperature)

The phosphor sheets produced in Examples and Comparative Examples were stored at room temperature for 500 hours and 1,000 hours while being illuminated (allowed to emit fluorescence) with a blue LED (peak wavelength=450 nm), and the brightness of each sheet was measured hourly to determine the brightness retention rate.

### (Storage Test at 60° C. and 90% RH)

The sheets produced in Examples and Comparative Examples were stored for 500 hours and 1,000 hours without being illuminated with a blue LED (peak wavelength=450 nm) in a test chamber having a temperature of 60° C. and a humidity of 90%, and the brightness of each sheet was measured hourly to determine the brightness retention rate.

### (Operation Test at 60° C. and 90% RH)

The sheets produced in Examples and Comparative Examples were stored for 500 hours and 1,000 hours while being illuminated with a blue LED (peak wavelength=450 nm) in a test chamber having a temperature of 60° C. and a humidity of 90%, and the brightness of each sheet was measured hourly to determine the brightness retention rate.

A phosphor sheet having a superior durability and a higher brightness is characterized by comprising complex particles having a larger particle size and a smaller surface area. When the complex particles have a large size, an extraneous attack from a resin caused by a reaction or the like is inhibited, so that good durability is obtained. A part of the complex subjected to an extraneous attack becomes transparent, resulting in the disappearance of emission.

TABLE 2

| | | Comparative |
|---|---|---|
| Phosphor sheet | Example 2 | Example 2 |

| | | |
|---|---|---|
| Complex (added | Example 1 | Comparative |
| amount) | (0.15 g) | Example |
| | | 1 (0.15 g) |

| | | | | |
|---|---|---|---|---|
| Acrylic resin | 3.5 | g | 3.5 | g |
| Thiol resin | 1.5 | g | 1.5 | g |
| Scattering agent: silicone | 0.3 | g | 0.3 | g |
| resin powder | | | | |
| Photoinitiator | 0.05 | g | 0.05 | g |
| Resin layer thickness | 75 | μm | 75 | μm |

| | | |
|---|---|---|
| Durability in operation at | 102% | 98% |

room temperature, 1,000 hr
(brightness retention rate)

| | | |
|---|---|---|
| Durability in operation at | 87% | 65% |

60° C. and 90% RH, 1,000 hr
(brightness retention rate)

| | | |
|---|---|---|
| Durability in storage at | 94% | 92% |

60° C. and 90% RH, 1,000 hr
(brightness retention rate)

| | | |
|---|---|---|
| Durability in operation at | 101% | 100% |

room temperature, 500 hr
(brightness retention rate)

| | | |
|---|---|---|
| Durability in operation at | 95% | 75% |

60° C. and 90% RH, 500 hr
(brightness retention rate)

| | | |
|---|---|---|
| Durability in storage at | 96% | 96% |

60° C. and 90% RH, 500 hr
(brightness retention rate)

### Production of Phosphor Sheets of Examples 3 and 4

Phosphor sheets of Examples 3 and 4 having a bilayer structure were produced using the complex of Example 1. The raw materials used, the results, and the like are shown in Table 3.

A resin composition was obtained by mixing 0.30 g of the complex of Example 1, 7.50 g of an acrylic resin, 2.50 g of a thiol resin, 0.30 g of a scattering agent (silicone resin powder), and 0.10 g of a photoinitiator. The thus obtained resin composition was applied to a barrier film and made into the form of a sheet. This sheet was irradiated with UV light to UV-cure the sheet-form resin.

Subsequently, a resin composition was obtained by mixing 1.20 g of green chalcopyrite-type quantum dots, 7.50 g of an acrylic resin, 2.50 g of a thiol resin, 0.30 g of a scattering agent (silicone resin powder), and 0.10 g of a photoinitiator. The thus obtained resin composition was applied to the previously UV-cured sheet-form resin and then covered with a barrier film. The resultant was UV-cured by irradiation with UV light, whereby a phosphor sheet of Example 3 having a bilayer structure was obtained. The thickness of the resin layer (sheet) (excluding the barrier film) was 150 μm.

A phosphor sheet of Example 4 was obtained in the same manner as in Example 3, except that 0.30 g of the complex of Example 1 was changed to a combination of 0.25 g of the complex of Example 1 and 0.05 g of InP quantum dots.

### Production of Phosphor Sheet of Comparative Example 3

A phosphor sheet of Comparative Example 3 having a bilayer structure was produced without using the complex of Example 1. The raw materials used, the results, and the like are shown in Table 3.

The phosphor sheet of Comparative Example 3 was obtained in the same manner as in Example 3, except that 0.30 g of the complex of Example 1 was changed to 0.27 g of InP quantum dots.

TABLE 3

| | | Comparative | | | | | | | | | |
|---|---|---|---|---|---|---|---|---|---|---|---|
| | | Example | | Example | | | | | | | |
| | | 3 | | 3 | | 4 | | 5 | | 6 | |
| First | Chalcopyrite quantum dots | — | | — | | — | | 1.5 | g | 1.5 | g |
| layer | Complex of Example 1 | — | | 0.30 | g | 0.25 | g | 0.3 | g | 0.25 | g |
| | InP quantum dots | 0.27 | g | — | | 0.05 | g | — | | 0.05 | g |
| | Scattering agent (silicone resin | 0.40 | g | 0.30 | g | 0.30 | g | 0.6 | g | 0.6 | g |
| | powder) | | | | | | | | | | |
| | Acrylic resin | 7.50 | g | 7.50 | g | 7.50 | g | 7.50 | g | 7.50 | g |
| | Thiol resin | 2.50 | g | 2.50 | g | 2.50 | g | 2.50 | g | 2.50 | g |
| | Photoinitiator | 0.10 | g | 0.10 | g | 0.10 | g | 0.10 | g | 0.10 | g |

| | | | | | | | | | |
|---|---|---|---|---|---|---|---|---|---|
| Second | Chalcopyrite quantum dots | 3.00 | g | 1.20 | g | 1.20 | g | — | — |
| layer | Scattering agent (silicone resin | 0.40 | g | 0.30 | g | 0.30 | g | — | — |
| | powder) | | | | | | | | |
| | Acrylic resin | 7.50 | g | 7.50 | g | 7.50 | g | — | — |
| | Thiol resin | 2.50 | g | 2.50 | g | 2.50 | g | — | — |
| | Photoinitiator | 0.10 | g | 0.10 | g | 0.10 | g | — | — |

| | | | | | | | | | | |
|---|---|---|---|---|---|---|---|---|---|---|
| Resin layer thickness | 150 | μm | 150 | μm | 150 | μm | 75 | μm | 75 | μm |

| | | | | | |
|---|---|---|---|---|---|
| Relative value of sheet brightness | 100% | 116% | 112% | 117% | 116% |
| Durability in operation at 60° C. and 90% RH | — | 102% | 95% | 93% | 80% |
| (500-hr brightness retention rate) | | | | | |

The phosphor sheets of Example 3 and 4 had excellent durability (500-hr brightness retention rate) in operation at 60° C. and 90% RH. In addition, taking the brightness of the phosphor sheet of Comparative Example 3 as 100% (standard), the phosphor sheets of Example 3 and 4 both had a higher brightness.

### Production of Phosphor Sheets of Examples 5 and 6

Phosphor sheets of Examples 5 and 6, which had a single-layer structure different from that of the phosphor sheet of Example 2, were produced using the complex of Example 1. The raw materials used, the results, and the like are shown in Table 3.

A resin composition was obtained by mixing 0.30 g of the complex of Example 1, 1.50 g of green chalcopyrite-type quantum dots, 7.50 g of an acrylic resin, 2.50 g of a thiol resin, 0.60 g of a scattering agent (silicone resin powder), and 0.10 g of a photoinitiator. The thus obtained resin composition was made into the form of a sheet, and barrier films were arranged above and below this resin composition sheet to sandwich the sheet. This sheet was irradiated with UV light to UV-cure the resin of the sheet, whereby a phosphor sheet of Example 5 was obtained. The thickness of the resin layer (sheet) (excluding the barrier films) was 75 μm.

A phosphor sheet of Example 6 was obtained in the same manner as in Example 5, except that 0.30 g of the complex of Example 1 was changed to a combination of 0.25 g of the complex of Example 1 and 0.05 g of InP quantum dots.

The phosphor sheets of Example 5 and 6 had excellent durability (500-hr brightness retention rate) in operation at 60° C. and 90% RH. In addition, taking the brightness of the phosphor sheet of Comparative Example 3 as 100% (standard), the phosphor sheets of Example 5 and 6 both had a higher brightness.

### Example 7: Synthesis of Complex Comprising Europium Coordinated with Both H₂1,4-Acebn and Btfa⁻

A THF solution was obtained by adding 113.7 g of a white solid powder [EuIII(BTFA)₃ (H₂O)₂)] to 390 ml of THF.

A chloroform solution was obtained by adding a solid powder (a4) N,N′-bis(hydroxyphenylacetylidene)-1,4-butanediamine (H₂1,4-acebn) [HO—C₆H₄—C(CH₃)═N—(CH₂)₄—N═C(CH₃)—C6H₄—OH: 44.3 g] (benzene rings are both ortho-substituted) to chloroform.

The above-obtained THE solution and chloroform solution were added at once to ethanol comprising crystals of a complex at room temperature, and the resultant was continuously stirred for a day. The resulting precipitated solid was filtered. Chloroform was removed by vacuum distillation, whereby a complex of Example 7 was obtained.

The physical properties of the complex of Example 7 are shown in Table 5.

### Example 8: Synthesis of Complex Having Al₂O₃-Coating on Outside and Comprising Europium Coordinated with Both H₂1,4-Acebn and Btfa⁻

A coating made of an inorganic material was formed on the outside of a metal complex by atomic layer deposition (ALD). The following formation method was employed.

One cycle of an ALD reaction process comprises four steps. The inside of a reaction tube is purged with nitrogen gas prior to the cycle; a precursor gas is allowed to adsorb to the surface of a phosphor in Step 1; excess precursor gas not adsorbing to the surface is discharged in Step 2; a reaction gas is introduced and allowed to react with the precursor gas adsorbed to the surface of the phosphor in Step 3; and unreacted excess reaction gas is discharged in Step 4. This one cycle yields a single layer of an atomic film, and films are formed by repeating the cycle until a prescribed film thickness is obtained. The gasses are introduced via two inlets arranged inside the reaction tube.

A mixture obtained by adding 0.3% by weight of nano-alumina manufactured by Nippon Aerosil Co., Ltd. to 100 g of the metal complex of Example 7 was placed in a reaction tube. The temperature of the reaction tube was set at 100° C., and the inside of the reaction tube was purged with nitrogen gas, after which an ALD reaction process was initiated under the conditions shown in Table 4 below. As the precursor gas of Step 1, nitrogen gas bubbled in trimethylaluminum(TMA: Al (CH₃)₃) was used; as the reaction gas of Step 3, a mixed gas of oxygen and nitrogen that was bubbled in pure water was used; and nitrogen gas was used for discharging excess gases in Steps 2 and 4. After the completion of the reaction process, the inside of the reaction tube was thoroughly purged with nitrogen gas, and the resulting metal complex was subsequently taken out, whereby a metal complex of Example 8 was obtained. The physical properties of the thus obtained complex of Example 8 are shown in Table 5.

TABLE 4

| | | Gas type | | | | | |
|---|---|---|---|---|---|---|---|
| | | | | | N₂ | Intro- | Number |
| ALD | | | | | TMA | duction | of cycles |
| Coating | Condition | N₂ | O₂ | N₂ | bubbling | time (sec) | (cycles) |
| Gas inlet | | Inlet 1 | | Inlet 2 | | | |
| Gas flow | Step 1 | 1.4 | | 0.6 | 0.1 | 9 | |
| rate | TMA | | | | | | |
| (L/min) | introduction | | | | | | |
| | carrier gas: N₂ | | | | | | |
| | Step 2 | 1.4 | | 0.8 | | 30 | 230 |
| | N₂ purging | | | | | | |
| | Step 3 | 1.0 | 0.4 | 0.8 | | 9 | |
| | Bubbling in pure | (with | (with | | | | |
| | water | bubbling | bubbling | | | | |
| | Introduction of | in water) | in water) | | | | |
| | N₂ and O₂ | | | | | | |
| | Step 4 | 1.4 | | 0.8 | | 30 | |
| | N₂ purging | | | | | | |

TABLE 5

| | | Example | Example 8 |
|---|---|---|---|
| | | 7 | (with coating) |
| Median particle | | 17.5 μm | 18.3 μm |
| size D50 | | | |
| σlog | | 0.810 | 0.816 |
| x | | 0.672 | 0.672 |
| y | | 0.327 | 0.328 |
| Y | | 54.9 | 51.6 |
| ENG | | 83.5 | 78.6 |
| λp | | 614 | 614 |
| Full width at | | 5.2 | 5.2 |
| half maximum | | | |
| IQE | | 76.6 | 75 |
| EQE | | 61 | 57.7 |
| Reflectance | 450 nm | 18.2% | 21.4% |
| | 730 nm | 96.0% | 96.0% |
| Al₂O₃ | Analysis | | 0.52% |
| | value | | |

### Production of Phosphor Sheets of Examples 9 and 10

Phosphor sheets of Examples 9 and 10, which had the same single-layer structure as the phosphor sheet of Example 5, were produced using the complexes of Examples 7 and 8, respectively. The raw materials used, the results, and the like are shown in Table 6.

A resin composition was obtained by mixing 0.15 g of the complex of Example 7, 0.60 g of green chalcopyrite-type quantum dots, 3.50 g of an acrylic resin, 1.50 g of a thiol resin, 0.30 g of a scattering agent (silicone resin powder), and 0.05 g of a photoinitiator. The thus obtained resin composition was made into the form of a sheet, and barrier films were arranged above and below this resin composition sheet to sandwich the sheet. This sheet was irradiated with UV light to UV-cure the resin of the sheet, whereby a phosphor sheet of Example 9 was obtained. The thickness of the resin layer (sheet) (excluding the barrier films) was 75 μm.

A phosphor sheet of Example 10 was obtained in the same manner as in Example 9, except that the complex of Example 7 was changed to the complex of Example 8.

TABLE 6

| | | Example | | Example | |
|---|---|---|---|---|---|
| | | 9 | | 10 | |
| Single | Chalcopyrite quantum dots | 0.60 | g | 0.60 | g |
| layer | Complex of Example 7 or 8 | 0.15 | g | 0.15 | g |
| | Scattering agent (silicone | 0.30 | g | 0.30 | g |
| | resin powder) | | | | |
| | Acrylic resin | 3.50 | g | 3.50 | g |
| | Thiol resin | 1.50 | g | 1.50 | g |
| | Photoinitiator | 0.05 | g | 0.05 | g |

| Resin layer thickness | 75 | μm | 75 | μm |
|---|---|---|---|---|
| Durability in operation at 60° C. and 90% RH | 84% | | 89% | |
| (500-hr brightness retention rate) | | | | |
| Durability in operation at 60° C. and 90% RH | 70% | | 75% | |
| (1,000-hr brightness retention rate) | | | | |

The phosphor sheets of Example 9 and 10 had excellent durability (500-hr brightness retention rate) in operation at 60° C. and 90% RH. In addition, taking the brightness of the phosphor sheet of Comparative Example 3 as 100% (standard), the phosphor sheets of Example 9 and 10 both had a higher brightness.

Further, the phosphor sheet of Example 10, in which the Al₂O₃-coated complex of Example 8 was used, exhibited a superior durability (500-hr brightness retention rate) in operation at 60° C. and 90% RH and a superior durability (1,000-hr brightness retention rate) in operation at 60° C. and 90% RH as compared to the phosphor sheet of Example 9 in which the complex of Example 7 that was not coated with Al₂O₃ was used.

### INDUSTRIAL APPLICABILITY

The rare earth metal complex phosphor according to one embodiment of the present invention can have an extended durability. Therefore, the rare earth metal complex phosphor according to one embodiment of the present invention can be suitably used for the production of a phosphor sheet and a light emitting device.

### Related Application

This patent application claims priority under Article 4 of the Paris Convention based on Japanese Patent Applications No. 2023-062203 filed in Japan on Apr. 6, 2023 and No. 2024-012136 filed in Japan on Jan. 30, 2024, the entireties of which are incorporated herein by reference

1. A method of producing a metal complex phosphor having an emission peak wavelength of 600 nm to 635 nm, the method comprising:
preparing a ligand that is represented by the following Chemical Formula (I) and comprises two sets of azomethine groups, and dissolving this ligand in a first solvent to prepare a solution (1);
preparing a rare earth metal complex that comprises a β-diketonato ligand represented by the following Chemical Formula (II) but does not comprise the ligand represented by Chemical Formula (I), and dissolving this rare earth metal complex in a second solvent to prepare a solution (2); and
mixing the solution (1) and the solution (2):
Chemical Formula (I): 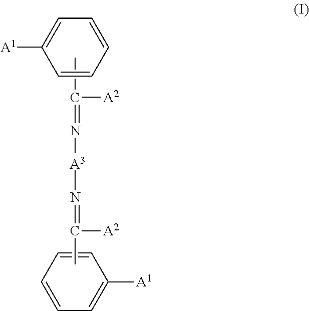
[wherein,
A¹ represents an OH group, an OD group, an SH group, or an SD group,
A² is selected from hydrogen, deuterium, C1 to C30 alkyl groups, C3 to C30 cycloalkyl groups, C1 to C30 perhalogenated alkyl groups, and C3 to C30 perhalogenated cycloalkyl groups, which groups optionally have one or more substituents selected from the following group (G):
aromatic groups;
perhalogenated aromatic groups;
heteroaromatic groups comprising at least one heteroatom in a ring;
linear or branched C1 to C30 alkyl groups;
linear or branched C1 to C30 perhalogenated alkyl groups;
linear or branched C3 to C30 alkenyl groups;
linear or branched C3 to C30 perhalogenated alkenyl groups;
C3 to C30 cycloalkyl groups;
C3 to C30 perhalogenated cycloalkyl groups;
C3 to C30 cycloalkenyl groups;
C3 to C30 perhalogenated cycloalkenyl groups; and
C3 to C30 alkynyl groups, and
halogeno groups,
A³ is selected from C2 to C30 alkylene groups optionally having one or more substituents selected from the group (G) and halogeno groups,
regarding a benzene ring to which A¹ and an azomethine group are both bound, two adjacent carbon atoms of the benzene ring that are not bound with A¹ and the azomethine group are optionally connected via —C₄H₄— to form a naphthalene ring, and
the benzene ring and the optionally-formed naphthalene ring optionally further have one or more substituents selected from the group (G) and halogeno groups]; and
Chemical Formula (II): 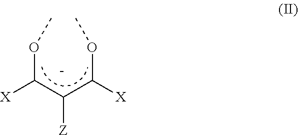
[wherein,
Xs represent substituents that are optionally the same as or different from each other and are selected from the group (G), and
Z represents a fluorine atom, a chlorine atom, a bromine atom, an iodine atom, a cyano group, a methyl group, an ethyl group, a phenyl group, a hydrogen atom, or a deuterium atom].

2. The method of producing a metal complex phosphor according to claim 1, the method comprising mixing the solution (1) and the solution (2) such that a concentration increase rate represented by the following Equation (1) is 0.00875 (M/hr) or less:
(Amount of increase in concentration of metal complex phosphor)/(Time from start to completion of mixing) (1).

3. The method of producing a metal complex phosphor according to claim 1,
wherein
the first solvent comprises a halogen-based solvent, and
the second solvent comprises an ether-based solvent.

4. The method of producing a metal complex phosphor according to claim 1, the method comprising further mixing the solution (1) and the solution (2) in the presence of a third solvent.

5. The method of producing a metal complex phosphor according to claim 4, wherein the third solvent comprises an alcohol-based solvent.

6. The method of producing a metal complex phosphor according to claim 1, the method further comprising coating the surface of the metal complex phosphor with an inorganic member or an organic member at 200° C. or lower.

7. A metal complex phosphor, comprising a rare earth metal complex and having a D50 particle size of 12 μm to 100 μm,
wherein
the rare earth metal complex comprises at least one chemical structure selected from the following Chemical Formulae (III) and (IV),
the rare earth metal is 8-coordinate, and
the metal complex phosphor has an emission peak wavelength of 600 nm to 635 nm:
Chemical Formula (III): 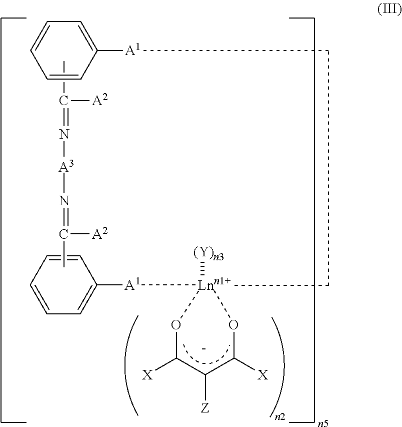
[wherein,
Ln represents a rare earth metal atom,
n1 represents 2 or 3,
regarding a β-diketonato ligand, Xs represent substituents that are optionally the same as or different from each other and are selected from the following group (G):
aromatic groups;
perhalogenated aromatic groups;
heteroaromatic groups comprising at least one heteroatom in a ring;
linear or branched C1 to C30 alkyl groups;
linear or branched C1 to C30 perhalogenated alkyl groups;
linear or branched C3 to C30 alkenyl groups;
linear or branched C3 to C30 perhalogenated alkenyl groups;
C3 to C30 cycloalkyl groups;
C3 to C30 perhalogenated cycloalkyl groups;
C3 to C30 cycloalkenyl groups;
C3 to C30 perhalogenated cycloalkenyl groups; and
C3 to C30 alkynyl groups,
Z represents a fluorine atom, a chlorine atom, a bromine atom, an iodine atom, a cyano group, a methyl group, an ethyl group, a phenyl group, a hydrogen atom, or a deuterium atom,
n2 represents an integer of 1 to 3,
Y is optionally at least one selected from a perchlorate ion, a nitrate ion, a carboxylate ion, and a halide ion,
n3 represents an integer of 0 to 2,
regarding a ligand that comprises two sets of azomethine groups:
A¹ represents an OH group, an OD group, an SH group, or an SD group,
A² is selected from hydrogen, deuterium, C1 to C30 alkyl groups, C3 to C30 cycloalkyl groups, C1 to C30 perhalogenated alkyl groups, and C3 to C30 perhalogenated cycloalkyl groups, which groups optionally have one or more substituents selected from the group (G) and halogeno groups,
A³ is selected from C2 to C30 alkylene groups optionally having one or more substituents selected from the group (G) and halogeno groups,
regarding a benzene ring to which A¹ and an azomethine group are both bound, two adjacent carbon atoms of the benzene ring that are not bound with A¹ and the azomethine group are optionally connected via —C₄H₄— to form a naphthalene ring,
the benzene ring and the optionally-formed naphthalene ring optionally further have one or more substituents selected from the group (G) and halogeno groups, and
n5 represents an integer of 2 or larger]; and
Chemical Formula (IV): 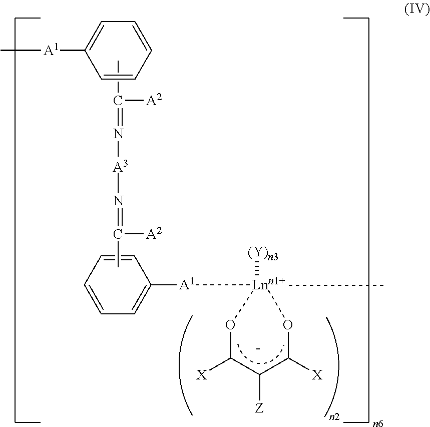
[wherein, all symbols have the same meaning as in Chemical Formula (III), except that n6 represents an integer of 1 or larger].

8. The metal complex phosphor according to claim 7, having a specific gravity of 1.570 g/cm³ to 2.000 g/cm³.

9. The metal complex phosphor according to claim 7, comprising a coating formed of an inorganic member or an organic member on the outside.

10. A phosphor sheet, comprising the metal complex phosphor according to claim 7 in a resin or a glass.

11. The phosphor sheet according to claim 10, comprising quantum dots having an emission peak wavelength of 515 nm to 540 nm.

12. The phosphor sheet according to claim 11, comprising the quantum dots and the metal complex phosphor in a single layer.

13. The phosphor sheet according to claim 11, comprising:
a first layer that comprises the quantum dots; and
a second layer that comprises the metal complex phosphor and quantum dots having an emission peak wavelength of 600 nm to 650 nm.

14. A light emitting device, comprising:
the phosphor sheet according to claim 10; and
a light emitting element having an emission peak wavelength of 380 nm to 490 nm.
